(19) United States
(12) Patent Application Publication
(10) Pub. No.: US 2004/0159935 A1
(43) Pub. Date: Aug. 19, 2004

(54) Thermally optimized conductive block

(76) Inventor: Prosenjit Ghosh, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/367,264

(22) Filed: Feb. 14, 2003

(51) Int. Cl. H01L 23/34

(52) U.S. Cl. 257/712

(57) ABSTRACT

A thermally conductive member is disclosed. In one embodiment, an apparatus has a thermally conductive member having a cavity at a first end, the first end of the thermally conductive member to communicate with a heat dissipating device and a second end of the thermally conductive member to communicate with a heat generating device. In another embodiment, the cavity is to accept an insulating material. In a further embodiment, the thermally conductive member is integrated with an enclosure of a computing device.

### FIELD OF THE INVENTION

Embodiments of the present invention relate to heat management and more particularly to heat management using thermal conductors.

### BACKGROUND

Heat management can be critical in many applications. Excessive heat can cause damage to or degrade the performance of mechanical, chemical, electric, and other types of devices. Heat management becomes more critical as technology advances and newer devices continue to become smaller and more complex, and as a result run hotter.

Modern electronic circuits, because of their high density and small size, often generate a substantial amount of heat. Complex integrated circuits (ICs), especially microprocessors, generate so much heat that they are often unable to operate without some sort of cooling system. Further, even if an IC is able to operate, excess heat can degrade an IC's performance and can adversely affect its reliability over time. Inadequate cooling can cause problems in central processing units (CPUs) used in personal computers (PCs), which can result in system crashes, lockups, surprise reboots, and other errors. The risk of such problems can become especially acute in the tight confines found inside laptop computers and other portable computing and electronic devices.

Prior methods for dealing with such cooling problems have included using heat sinks, fans, and combinations of heat sinks and fans attached to ICs and other circuitry in order to cool them. However, in many applications, including portable and handheld computers, computers with powerful processors, and other devices that are small or have limited space, these methods may provide inadequate cooling.

### BRIEF DESCRIPTION OF THE DRAWINGS

FIG. 1 is a graph displaying the temperature across a surface of a heat source.

FIG. 2 illustrates a thermally conductive block according to an embodiment.

FIG. 3 illustrates a thermally conductive block and insulation according to an embodiment.

FIG. 4 is a graph showing surface temperatures on an IC using a thermally conductive block according to an embodiment.

FIG. 5 illustrates a thermally conductive block and insulation according to another embodiment.

### DETAILED DESCRIPTION

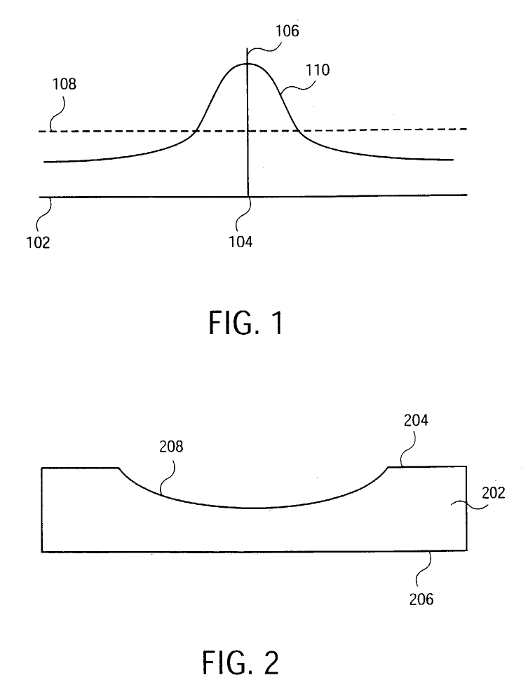

FIG. 1 is a graph displaying the temperature across a surface of a heat source. Modern integrated circuits (ICs) typically have increased transistor density and integrated die functionality, and as a result, die surface temperature and surface temperature nonuniformities are increasing. This can be illustrated using FIG. 1. An IC is a heat source, but many other heat sources may mirror the pattern of uneven heat distribution demonstrated in FIG. 1.

The x-axis 102 represents a distance from the center of a heat source, and the center point 104 represents the center of the heat source. The y-axis 106 represents the temperature at a corresponding distance from the center of the heat source. A surface temperature limit 108 represents a maximum safe operating temperature for a heat source. The temperature curve 110 shows the temperature at certain distances from the heat source's center 104. As can be seen in FIG. 1, the temperature curve 110 spikes near the center of the heat source 104 and exceeds the surface temperature limit 108. Nonuniformities, or hot spots, as illustrated in FIG. 1 are undesirable in any system or device, but particularly in those systems or devices utilizing high power or dense integrated circuits. These hot spots are especially undesirable in heat sources that are part of small systems or devices where heat dissipation is difficult due to the small size of an enclosure surrounding the heat source.

FIG. 2 illustrates a thermally conductive block according to an embodiment. A thermally conductive block 202 has a first end 204, a second end 206, and a cavity 208. The first end 204 is to communicate with a heat dissipating device, and the second end 206 is to communicate with a heat generating device. The thermally conductive block 202 can be any heat conducting member capable of having a cavity, and can be adapted or molded for specific applications. As shown in FIG. 2 the cavity 208 is centered in the top of the conductive block 202. However, it is apparent that the cavity 208 may be positioned elsewhere within the thermally conductive block 202. The cavity 208 as shown in FIG. 2 is also shaped hemispherically. It is clear, though, that the cavity 208 may assume other shapes, such as a rectangular shape, depending on the requirements of the application. The shape of the cavity 208 can be determined by considering the desired thermal effect, the available manufacturing methodologies, and volumetric constraints of the specific application. In one embodiment, the shape of the cavity 208 is a mirror image of a heat source's temperature profile. In another embodiment, the cavity 208 is adapted to accept an insulating material. However, it is understood that air is an acceptable insulator, so the cavity 208 may also be filled with nothing other than air and still be effective.

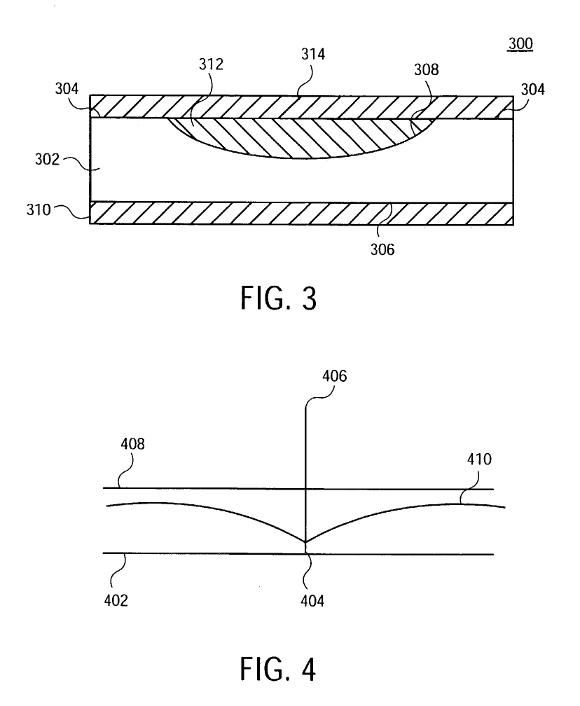

FIG. 3 illustrates a thermally conductive block and insulation according to an embodiment. The cooling device 300 includes a thermally conductive block 302 having a first end 304, a second end 306, and a cavity 308. The thermally conductive block 302 may be designed so as to integrate with an enclosure, such as a chassis, of a device using heat generating device 310. The second end 306 of the thermally conductive block 302 communicates with a heat generating device 310. The heat generating device 310 may be circuitry such as an integrated circuit (IC), a processor, a central processing unit (CPU), a bare die, an application specific integrated circuit (ASIC), a graphics processor, a chipset, or any other type of circuitry that will require cooling. Further, any device that generates heat may be adaptable to the cooling system 300. The first end 304 of the thermally conductive block 302 is in communication with a heat dissipating device 314. The heat dissipating device 314 may be a heat sink, a heat spreader, a heat pipe, a fan, or any other appropriate heat dissipating device.

In one embodiment, the cavity 308 is to accept an insulating material 312. However, as mentioned above, air is an acceptable insulator, and so an insulating material 312 is not necessary for the thermally conductive block 302 to be effective. However, in some applications, an insulating material 312 may be desirable or necessary. The cavity 308 and the insulating material 312 help to direct heat from the center of the heat generating device 310 toward the edges of the heat dissipating device 314. As illustrated in FIG. 1, a hot spot is often present at the center of a heat-generating device. Therefore, any heat dissipating device connected with a heat generating device that suffers from nonuniformities and hot spots would be overworked at its center and underutilized at its edges.

The insulating material 312 and the cavity 308 of the thermally conductive block 302 help to direct heat from the heat generating device 310 toward the edges of the heat dissipating device 314 to better utilize the capacity of the heat dissipating device 314. If no cavity 308 were present in thermally conductive block 302, the heat rising from the heat generating device 310 would, for the most part, move directly upward, and would cause a hot spot such as is illustrated in FIG. 1. Both air and any insulating material 312 have low thermal conductivities, and the thermally conductive block 302 has a high thermal conductivity. Heat will tend to travel along the path of lowest resistance, or highest conductivity. As a result, the heat will tend to travel through the thermally conductive block 302 rather than through the cavity 308 or the insulating material 312, and some of the heat that would ordinarily travel through the center of the thermally conductive block 302 will be diverted to the edges. Therefore, when heat rises from the heat generating device 310 and is transferred into the thermally conductive block 302, more heat will tend toward the outside of the thermally conductive block 302, and as a result to the edges of the heat dissipating device 314, because there is less resistance encountered when heat travels through the thermally conductive block 302 than when heat travels through the cavity 308 or through the insulating material 312. The existence of the cavity 302 will lead to a more even distribution of heat and better utilization of the heat dissipating device 314. This increased utilization of the heat dissipating device 314 will lead to an overall reduction of the operating temperature of the heat generating device 310. The increased utilization of the heat dissipating device 314 will also reduce the incidence of hot spots that may be caused by the heat generating device 310.

A thermally conductive block 302 may be constructed of any appropriate thermally conductive material and can be machined or molded to fit a specific application, as well as to fit a specific enclosure which may be required by the application. For example, the thermally conductive block 302 may be shaped and sized to fit a processor within the tight confines of a portable or hand held computer. The thermally conductive bock 302 may be made from aluminum, copper, graphite, magnesium, or any other appropriate material depending on the requirements of the system and the conductivity of the material. Further, the thermally conductive block 302 may also be constructed of nonhomogenous materials such as copper-tungsten or copper-graphite alloys, or a copper-aluminum matrix.

The insulating material 312 may be a solid material or a dispensable or porous material. As above, the insulating material 312 should have a low conductivity in comparison to the material used for the thermally conductive block 302. Further, the configuration of the thermally conductive block 302, the shape, the size and location of the cavity of 308 and the amount or type of insulating material 312 may all be changed and configured depending on the type of heat generating device 310 and the enclosure in which the heat generating device 310 will be operating. The insulating material 312 can be a closed- or open-celled foam, and the optimum material for each application can depend on the foam characteristics, the temperatures that the application will experience, and how much resistance and cooling is required by the application. Further, in another embodiment, the insulating material 312 is gaseous.

Portable computers and hand held electronic devices are becoming smaller and/or more powerful, and as a result are generating more heat. Many of these new electronic devices such as hand held computers require heat management not only for system stability and longevity but also to reduce the surface temperature of the hand held device. Hot spots caused by circuitry that is unevenly cooled can lead to ergonomically unacceptable conditions, making the use of such devices difficult and uncomfortable. A thermally conductive block can create a more even heat distribution and reduce overall surface temperatures on hand held devices and other devices that may often be handled by a user. This will allow such devices to become more powerful and smaller while still being useful.

FIG. 4 is a graph illustrating a surface temperature of a heat-generating device when using a thermally conductive block according to an embodiment. The x-axis 402 represents a distance from the center of a heat generating device 404. The y-axis 406 represents the surface temperature of a heat generating device. The surface temperature limit 408 is a maximum operating temperature that can be withstood by a heat generating device. Temperature curve 410 represents the temperature at the surface of the heat generating device. As can be seen from the graph, when using the thermally conductive block as described herein, the overall surface temperature of the heat generating device decreases, becomes more uniform, and avoids spikes. Further, as can be seen in FIG. 4, the heat generating device is now operating within its surface temperature operating limit 408. This is in comparison with FIG. 1 where the temperature of the heat generating device exceeds its surface temperature limit and is non uniform. Thus, as can be seen in FIG. 4, the thermally conductive block and the insulating material help to provide improved and more uniform cooling for a heat generating device.

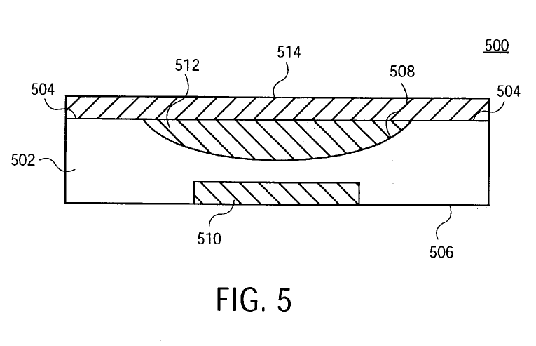

FIG. 5 illustrates a thermally conductive block and insulation according to another embodiment. The cooling device 500 includes a thermally conductive bock 502 having a first end 504, a second end 506, and a cavity 508. The second end 506 is in communication with a heat generating device 510. The first end 504 is in communication with a heat dissipating device 514. In one embodiment, an insulating material 512 is found within cavity 508. As above, in another embodiment, the cavity 508 is filled with air. Also as above, the cavity 508 may be of a variety of sizes and locations in the thermally conductive block 502, depending on the needs of the application. Also as above, the thermally conductive block 502 may be made of different materials. Further, the insulating material 512 may be solid or porous, and may be made of any appropriate material.

As shown in FIG. 5, the thermally conductive block 502 is shaped so as to include an aperture which encloses the heat generating device 510, resulting in a larger thermally conductive block 502. A larger thermally conductive block 502 can provide additional cooling because it can move more heat away from the heat generating device 510 than a smaller block can. Depending on the space and heat dissipation requirements, this configuration of a thermally conductive block 502 may be desirable if additional heat dissipating capacity is required, if heat generating device 510 is small enough to allow the larger block, or if the enclosure of which the system is placed is large enough to allow a larger thermally conductive block 502. It is clear that many other configurations of thermally conductive block 502 are also possible.

This invention has been described with reference to specific exemplary embodiments thereof. It will, however, be evident to persons having the benefit of this disclosure that various modifications and changes may be made to these embodiments without departing from the broader spirit and scope of the invention. The specification and drawings are, accordingly, to be regarded in an illustrative rather than a restrictive sense.

What is claimed is:

1. An apparatus, comprising:
a thermally conductive member having a cavity near a first end, the first end of the thermally conductive member to communicate with a heat dissipating device; and
a second end of the thermally conductive member to communicate with a heat generating device.

2. The apparatus of claim 1, wherein the cavity is to accept an insulating material.

3. The apparatus of claim 1, wherein the cavity is shaped hemispherically.

4. The apparatus of claim 1, wherein the conductive member further comprises an aperture at the second end to enclose the heat generating device.

5. The apparatus of claim 1, wherein the heat generating device is a processor die.

6. The apparatus of claim 1, wherein the heat dissipating device is a heat spreader.

7. The apparatus of claim 1, wherein the heat dissipating device is a heat sink.

8. The apparatus of claim 2, wherein the insulating material is porous.

9. The apparatus of claim 2, wherein the insulating material is solid.

10. The apparatus of claim 2, wherein the insulating material is gaseous.

11. The apparatus of claim 1, wherein the thermally conductive member is integrated with an enclosure of a computing device.

12. The apparatus of claim 11, wherein the enclosure is a chassis.

13. A thermally conductive member, comprising:
a first end to communicate with a heat dissipating device;
a second end to communicate with a heat generating device; and
a cavity located near the first end.

14. The thermally conductive member of claim 13, wherein the cavity is to accept an insulating material.

15. The apparatus of claim 13, wherein the cavity is shaped hemispherically.

16. The apparatus device of claim 13, wherein the second end further comprises an aperture to enclose the heat generating device.

17. The system of claim 14, wherein the insulating material is porous.

18. The system of claim 14, wherein the insulating material is solid.

19. The system of claim 14, wherein the insulating material is gaseous.

20. An system, comprising:
a thermally conductive member having a cavity near a first end;
a heat spreader or a heat sink coupled with the first end of the thermally conductive member; and
a second end of the thermally conductive member to communicate with a heat generating device.

21. The system of claim 20, wherein the cavity is to accept an insulating material.

22. The system of claim 20, wherein the cavity is shaped hemispherically.

23. The system device of claim 20, wherein the conductive member further comprises an aperture at the second end to enclose the heat generating device.
